(19) United States
(12) Patent Application Publication
(10) Pub. No.: US 2009/0035943 A1
(43) Pub. Date: Feb. 5, 2009

(54) Method of Fabricating for Semiconductor Device Fabrication

(76) Inventor: Inho Park, Dresden (DE)

Correspondence Address: SLATER & MATSIL, L.L.P., 17950 PRESTON ROAD, SUITE 1000, DALLAS, TX, 75252, US

(21) Appl. No.: 11/830,643

(22) Filed: Jul. 30, 2007

(51) Int. Cl. H01L 21/311; H01L 21/302

(52) U.S. Cl. 438/700; 438/751; 257/E21.536; 257/E21.038

(57) ABSTRACT

A method of fabricating a semiconductor device, includes providing a substrate having at least one first portion and at least one second portion. The first portion includes a semiconductor material and the second portion includes an electrically isolating material. An etching step is performed using an etchant in order to at least partially remove the first and the second portions. The etchant includes a NF₃/CH₄/N₂ plasma.

### BRIEF DESCRIPTION OF THE DRAWINGS

In the accompanying drawings:

FIGS. 1A-1C illustrate a semiconductor structure to which the method according to the invention can be applied;

FIGS. 2A-2D illustrate a method according to an embodiment of the invention; and

FIGS. 3A and 3B illustrate sectional views of a semiconductor structure.

### DETAILED DESCRIPTION OF ILLUSTRATIVE EMBODIMENTS

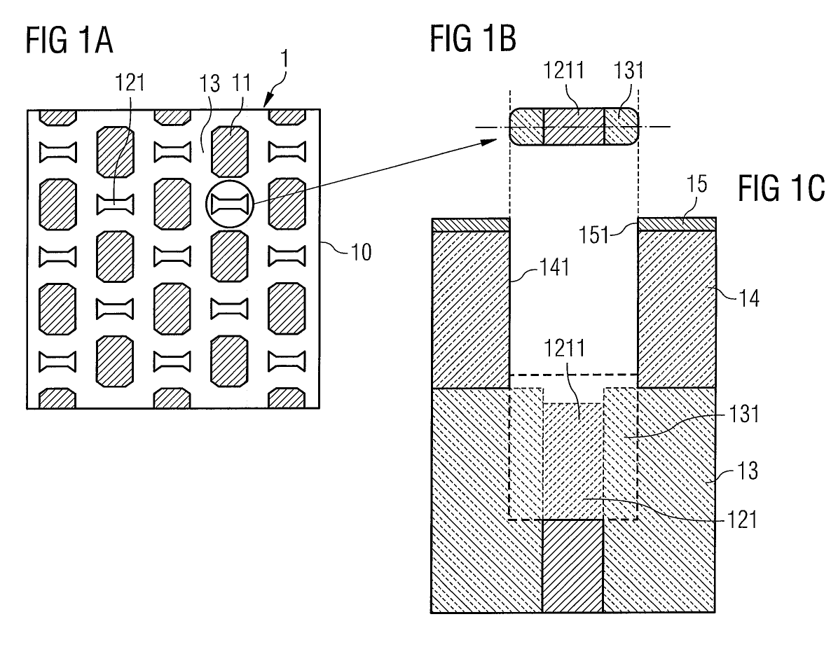

FIG. 1A relates to an array of storage cells 1 formed in a semiconductor substrate 10 (e.g., a silicon substrate). Each storage cell 1 comprises a deep trench capacitor 11 and a first portion of the substrate 10 in the form of an active area 121 consisting of doped substrate material. Further, each storage cell 1 comprises a shallow trench isolation 13, wherein a part 131 of the shallow trench isolation 13 forms a second portion of the substrate 10 as shown in FIG. 1B. The shallow trench isolation 13 surrounds the active areas 121 such that storage cells, of the array are electrically isolated from each other.

A detail of one of the storage cells is illustrated in FIGS. 1B (top down view) and 1C (sectional view). A hard mask layer 14 is located above the shallow trench isolation 13 and the active area 121, wherein the hard mask layer 14, consist of materials such as carbon, for example. A further layer 15 is created above the hard mask layer 14, which in an example comprises silicon oxynitride.

An additional device (such as a corner device) is to be generated in the region of the active area 121. For this, an opening 151 is created in the further layer 15 and an opening 141 is created in hard mask layer 14 such that the active area 121 and the part 131 of the shallow trench isolation 13 are uncovered.

Using the openings 151 and 141, the part 131 of the shallow trench isolation 13 and an upper part 1211 of the active area 121 can be removed in preparation of the fabrication of the device. In FIG. 1C, the parts 131 and 1211 of the shallow trench isolation 13 and the active area 121, respectively, that are to be removed are identified by a dashed line.

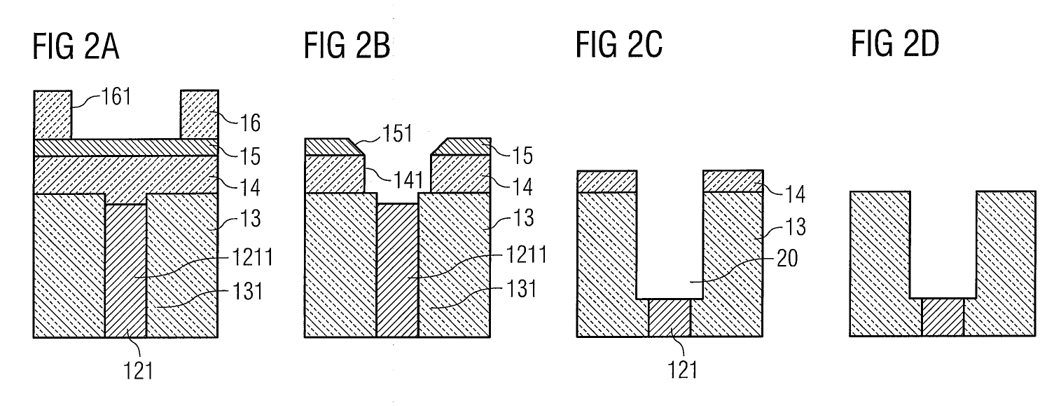

Referring to FIGS. 2A-2D. These figures illustrate a process flow according to an embodiment of the invention, wherein the process flow is explained with respect to the structure shown in FIGS. 1A-1C, i.e., the process is employed for removing the part 131 of the shallow trench isolation 13 and the upper part 1211 of the active area 121.

According to FIG. 2A a resist mask 16 comprising an opening 161 is used to structure the underlying (further) layer 15 (comprising, e.g., silicon oxynitride), wherein the further layer 15 is etched such that the opening 151 is created as shown in FIG. 2B. The etching of the further layer 15 can be carried out using a CHF₃/CF₄ plasma; for example, with a pressure of 100 mTorr (13.3 Pa) and an excitation power of 500 W, for example. However, other etchants and/or other etching conditions are possible.

In a subsequent step depicted in FIG. 2B, another etchant is used to generate the opening 141 in the hard mask layer 14 (comprising, e.g., carbon). The etchant can, e.g., comprise a HBr/O₂/N₂ plasma, wherein in an example an excitation power of approximately 900 W (upper electrode) and 50 W (lower electrode) is used. Of course, other plasma conditions can be employed. The resulting structure is shown in FIG. 2B depicting that the openings 141 and 151 uncover the upper portion 1211 of the active area 121 and the part 131 of the shallow trench isolation 13. In an example the resist mask 16 is removed during the etching of the hard mask layer 14.

Subsequently, the upper portion 1211 and the part 131 of the shallow trench isolation 13 have to be etched. For this, a NF₃/CH₄/N₂ plasma is used permitting that both the upper portion 1211 and the part 131 are etched simultaneously (i.e. non-selectively in one step). In detail, the NF₃ content (with exemplary flow rates in the range of approximately 60-80 sccm) of the etching plasma has a higher etch rate for oxide than for oxynitride or nitride. Further, with the inventive plasma the C and F contamination of silicon is low. The CH₄ content (with exemplary flow rates in the range of approximately 10-30 sccm) of the plasma quickly generates polymers on different materials (i.e. on the portion 1211 and on part 131, respectively) at different deposition rates. The N₂ content (with exemplary flow rates in the range of approximately 10-30 sccm) of the plasma activates both polymerization and F generation.

It is possible, although not obligatory, that the NF₃/CH₄/N₂ composition and/or the plasma conditions (excitation frequency and excitation power) are chosen to allow the upper portion 1211 and the shallow trench isolation part 131 to be etched with essentially the same etch rates.

Due to the removal of the upper portion 1211 and the part 131 a recess 20 is generated (FIG. 2C), wherein the further layer 15 has been removed, also. In a further step, the remaining hard mask layer 14 is stripped using an etchant in the form of, e.g., an O₂/N₂ plasma (FIG. 2D). Exemplary plasma conditions comprise of a pressure of 10 mTorr (1.3 Pa) and an excitation power of approximately 1200 W (upper electrode) and 50 W (lower electrode).

The use of NF₃/CH₄/N₂ plasma on the one hand permits the upper portion 1211 and the part 131 to be etched in one step. Further, in particular, since the C and F contamination of the plasma relative to silicon is low, the etching can be carried out without having to change the process chamber (process tool). Furthermore, the etching of the further layer 15 (using, e.g., a CHF₃/CF₄ plasma) and the etching of the hard mask layer 14 (using, e.g., a HBr/O₂/N₂ plasma) can be carried out within the same process tool such that all process steps illustrated in FIGS. 2A-2D can be done in a single process tool, e.g., a silicon etch tool, without having to change the process tool.

In an embodiment of the invention, low pressure is used, e.g., in the range of 8-15 mTorr (1-2 Pa), providing a higher ion current selectively activating oxide etching. Further, a mid source power (e.g., in the range of 700-900 W) can be employed suppressing an excessive amount of plasma species. In another embodiment, a raised bias power (e.g., in the range of 150-200 W) is applied to utilize ions to enhance the selectivity to the hard mask layer (e.g., a carbon layer).

The first and the second portion can be an active area (e.g., comprising silicon) and a shallow trench isolation (e.g. comprising silicon oxide), respectively. The invention, however, is not restricted to the etching of active areas or shallow trench isolations. Other structures having a first portion comprising a semiconductor material and a second portion comprising an isolating material can be etched, e.g., other structures generated or used during the fabrication of an integrated circuit, in particular a storage device.

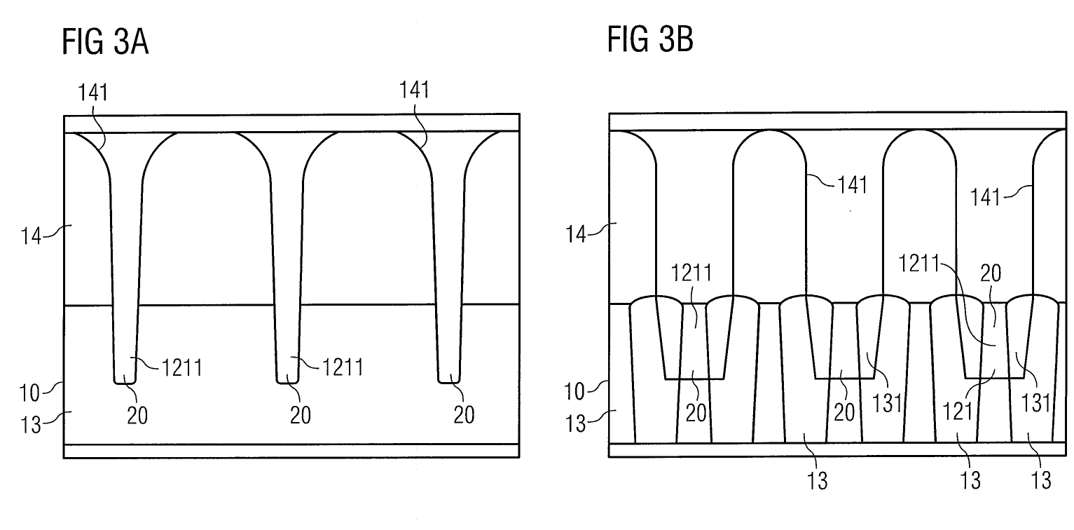

Referring to FIGS. 3A and 3B, another example of a semiconductor substrate 10 is illustrated on which the inventive method can be applied. FIG. 3A is a sectional view along a first direction (x-direction) and FIG. 3B is a sectional view along a second direction (y-direction) perpendicular to the first direction.

The substrate 10 comprises a plurality of first portions in the form of active areas 121 and a shallow trench isolation 13 which electrically isolates neighbouring active areas 121. Above the first and second portions 13 and 121, a carbon hard mask layer 14 is deposited. The hard mask layer 14 comprises openings 141 that were used to etch a hole-like opening 20 in the substrate 10 such that an upper portion 1211 of each active area 121 and a portion 131 of the shallow trench isolation 13 were removed.

1. A method of fabricating a semiconductor device, the method comprising:
providing a substrate comprising at least one first portion and at least one second portion, the first portion comprising a semiconductor material and the second portion comprising an electrically isolating material; and
performing an etching step using an etchant in order to at least partially remove the first and the second portion, wherein the first and the second portions are etched simultaneously and wherein the etchant comprises a NF₃/CH₄/N₂ plasma.

2. (canceled)

3. The method according to claim 1, wherein the NF₃/CH₄/N₂ composition and plasma conditions are chosen such that the first and the second portions are etched at the same rate.

4. The method according to claim 1, wherein the semiconductor material of the first portion comprises silicon.

5. The method according to claim 1, wherein the electrically isolating material comprises silicon oxide or silicon nitride.

6. The method according to claim 1, wherein the first portion is at least a part of an active area region of the semiconductor device.

7. The method according to claim 1, wherein the second portion extends adjacent to the first portion.

8. The method according to claim 1, wherein the second portion at least partially surrounds the first portion.

9. The method according to claim 8, wherein the second portion is at least a part of a shallow trench isolation of a storage cell array of the semiconductor device.

10. The method according to claim 1, further comprising forming a hard mask layer above the first and the second portions before the etching step.

11. The method according to claim 10, wherein
the hard mask layer is structured before the etching step such that an opening is formed in the hard mask layer, the opening uncovering the first portion and at least a part of the second portion; and
the etching step is performed using the structured hard mask layer.

12. The method according to claim 11, wherein the hard mask layer comprises carbon.

13. The method according to claim 11, wherein the opening in the hard mask layer is formed using an etchant which comprises a HBr/O₂/N₂ plasma.

14. The method according to claim 11, further comprising forming a further layer above the hard mask layer before the hard mask layer is structured.

15. The method according to claim 14, further comprising:
forming an opening in the further layer before the hard mask layer is structured using a resist mask wherein, the opening in the further layer is used to form the opening in the hard mask layer.

16. The method according to claim 15, wherein the further layer comprises silicon oxynitride or consists of silicon oxynitride.

17. The method according to claim 15, wherein the opening in the further layer is formed using an etchant which comprises a CHF₃/CF₄ plasma.

18. The method according to claim 15, further comprising stripping the hard mask layer after performing the etching step for removing the first and the second portion.

19. The method according to claim 18, wherein the hard mask layer is stripped using an O₂/CF₄ plasma.

20. The method according to claim 13, wherein etching the first and second portions, forming an opening in the hard mask layer, forming an opening in a further layer, and stripping the hard mask layer are performed in a same process chamber.

21. The method according to claim 1, wherein the semiconductor device is a memory device.

22. A method of fabricating a semiconductor device, the method comprising:
providing a substrate comprising at least one first portion and at least one second portion, the first portion comprising a semiconductor material and the second portion comprising an electrically isolating material, wherein the first portion is at least a part of an active area region of the semiconductor device and the second portion is at least a part of a shallow trench isolation of a storage cell array of the semiconductor device; and
performing an etching step using an etchant in order to at least partially remove the first and the second portions, wherein the first portion and the second portion are etched simultaneously.

23. The method according to claim 22, wherein the etchant comprises a NF₃/CH₄/N₂ plasma.

24. The method according to claim 22, wherein the first and the second portions are etched at the same rate.

25. The method according to claim 22, wherein the first portion comprises silicon and the second portion comprises silicon oxide.

26. The method according to claim 22, wherein
a layer stack is created above the first and the second portions before the etching step, the layer stack comprising a carbon layer and a silicon oxynitride layer; and
the first and the second portions arc etched selectively with respect to the carbon layer and the silicon oxynitride layer.

27. The method according to claim 26, wherein the layer stack is etched to form a structure in the layer stack, the etching of the layer stack and the etching of the first and the second portions being performed within a same process chamber.
